(19) United States
(12) Patent Application Publication
(10) Pub. No.: US 2025/0067594 A1
(43) Pub. Date: Feb. 27, 2025

(54) Method and System for Generating a Warp Field

(71) Applicant: Chance M. Glenn, Victoria, TX (US)

(72) Inventor: Chance M. Glenn, Victoria, TX (US)

(21) Appl. No.: 18/180,667

(22) Filed: Mar. 8, 2023

Related U.S. Application Data
(60) Provisional application No. 63/317,712, filed on Mar. 8, 2022.

(51) Int. Cl. G01J 1/42; G01R 13/00

(52) U.S. Cl. CPC G01J 1/4257; G01R 13/00

(57) ABSTRACT

Exemplary embodiments are directed to a system having a resonant cavity at least partially filled with a dielectric material. The system also includes a laser source configured to emit a laser beam through a hole in the resonant cavity. An optical sensor captures at least a portion of laser beam that as passed through resonant cavity and generates a voltage based on the captured laser beam.

### RELATED APPLICATION

The present application claims the benefit of priority to U.S. Provisional Application No. 63/317,712 filed on Mar. 8, 2022, the entire content of which is hereby incorporated by reference in its entirety.

### FIELD

The present invention relates generally to a method and system for generating a warp field, and more particularly to generating a warp filed using electromagnetic and radio frequency principles.

### BACKGROUND

The ability to warp space time presents a provocative opportunity to take a quantum step in propulsion technology. Ideas proposed in 1994 by Alcubierre have been developed over the years to suggest that vessels could be made to be propelled at incredible speeds by the selective compression of spacetime in front of the ship and expanding behind it.

In Alcubierre's seminal paper, “The warp drive: hyper-fast travel within general relativity,” Class. Quant. Grav. 11, L73-L77 (1994), he describes the possibility of moving a ship through spacetime by compressing it in front of the craft and expanding it behind the craft, thus producing an apparent velocity, vs, in each direction. This warping of space time can produce apparent velocities that well exceed the speed of light yet does not violate Einstein's speed of light limit [3]. This has given many researchers and practitioners hope that we could build space vessels that could reach interstellar destinations within human lifetimes. The Alcubierre metric is described in equation (1) and is a hyperbolic metric in 3+1 space time. Equation (1) is as follows:

$$d s 2 = - d t 2 + ( d x - v s f ( r s ) d t ) 2 + d y 2 + d z 2 \qquad ( 1 )$$

FIG. 1A illustrates a shaping function f(rₛ) in accordance with the known Alcubierre metric. FIG. 1B illustrates a Yorke time contraction and expansion due to the shaping function in accordance with the known Alcubierre metric.

The shaping function, f(rₛ), is an expression that describes the warp field that needs to be created to provide movement in the desired direction and is a function of the radius from the center of the ship. In equation (1) the shaping function influences the x direction. Alcubierre offers a “top hat” shaping function described in equation (2). The expression for the Yorke time expansion and contraction, θ(rₛ), is in equation (3) wherein it is proportional to the derivative of the shaping function with respect to the radius. FIG. 2 shows the Yorke time response visually. What is desirable about the specific shaping function used is that it provides no space time distortion within a region where the ship can reside. Therefore, the passengers suffer no effects of time dilation or length contraction/expansion within that region.

$$f ( {r}_{s} ) = \frac{tanh ( σ ( {r}_{s} + R ) ) - tanh ( σ ( {r}_{s} - R ) )}{2 tanh ( σ R )} \qquad ( 2 )$$

$$and$$

$$θ ( {r}_{s} ) = {v}_{s} \frac{{x}_{s}}{{r}_{s}} \frac{df}{{dr}_{s}} \qquad ( 3 )$$

In these expressions R is the radius of the warp bubble and is the thickness of the warp bubble shell. There are no restrictions on the form of the shaping function, other than it provides a region of unaffected space time wherein passengers can reside. As we will discuss in the next section, the required energy density is impacted by the shaping function.

The expression that is derived by Alcubierre for the required energy density is shown in equation (4). It provides a negative value for the energy density which violates conditions for weak, dominant, and strong energy conditions as set forth by Hawking [8]. This suggests that the only way to distort space time is through the application of negative, or exotic, energy. While there has been much work to reduce the resulting magnitude of this energy from that within the entire known universe [9] to that of a small space vehicle [10], the solution is still a negative value. Some have even proposed the use of antimatter [11] and dark energy as a possible alternative [12], even though the existence of such an energy is theoretical at best [13].

$${T}^{00} = - \frac{1}{8 π} \frac{{v}_{s}^{2} {ρ}^{2}}{4 {r}_{s}^{2}} {( \frac{df}{{dr}_{s}} )}^{2} \qquad ( 4 )$$

The energy density is proportional to the square of the derivative of the shaping function with respect to the radius. For the shaping function described in equation (2) the energy density is large and negative over the region containing the warp field. The total energy is found by integrating over the whole space.

### SUMMARY

An exemplary system is disclosed comprising a resonant cavity at least partially filled with a dielectric material; a laser source configured to emit a laser beam through a hole in the resonant cavity; an optical sensor configured to capture at least a portion of laser beam that as passed through resonant cavity and generate a voltage based on the captured laser beam.

An exemplary method is disclosed, the method comprising: filling a resonant cavity at least partially with a dielectric material; emitting a laser beam through a hole in the resonant cavity; and capturing, at least a portion of laser beam that as passed through resonant cavity and generate a voltage based on the captured laser beam.

### DESCRIPTION OF THE DRAWINGS

Exemplary embodiments are best understood from the following detailed description when read in conjunction with the accompanying drawings. Included in the drawings are the following figures:

FIG. 1A illustrates a shaping function f(rₛ) in accordance with the known Alcubierre metric;

FIG. 1B illustrates a Yorke time contraction and expansion due to the shaping function in accordance with the known Alcubierre metric;

FIG. 2 illustrates a required energy density distribution for the known Alcubierre “top hat” shaping function;

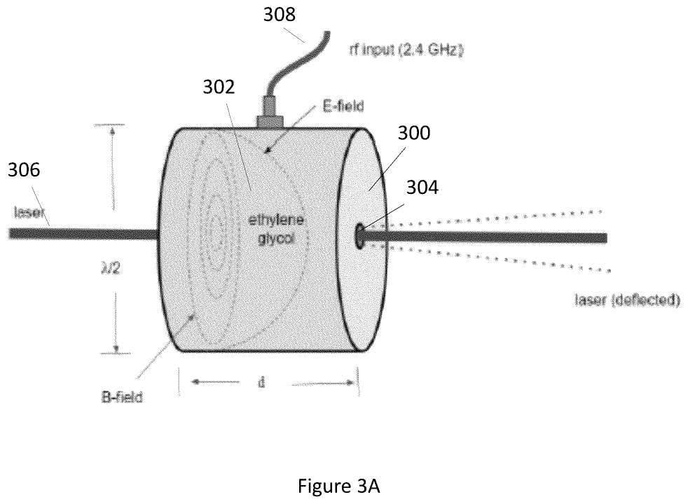

FIGS. 3A and 3B are diagrams of a cylindrical cavity in accordance with an exemplary embodiment of the present disclosure.

FIG. 4 illustrates a shaping function formed inside of the cylindrical cavity based upon the electric flux density in TM010 mode in accordance with an exemplary embodiment of the present disclosure.

FIG. 5A illustrates an energy density distribution of the cylindrical resonant cavity filled with a lossy dielectric in accordance with an exemplary embodiment of the present disclosure.

FIG. 5B illustrates a Yorke time structure based upon the cylindrical resonant cavity filled with a lossy dielectric in accordance with an exemplary embodiment of the present disclosure.

FIGS. 6A and 6B illustrate exemplary systems for testing spacetime variations in accordance with an exemplary embodiment of the present disclosure.

FIG. 7 illustrates an energy distribution plot generated by the systems of FIGS. 6A and 6B in accordance with an exemplary embodiment of the present disclosure.

FIG. 8 illustrates interference fringes caused by distortion in the cylindrical resonant cavity in accordance with an exemplary embodiment of the present disclosure.

FIG. 9 illustrates a characterization curve showing the radius of a warp bubble formed in the resonant cavity in accordance with an exemplary embodiment of the present disclosure.

Further areas of applicability of the present disclosure will become apparent from the detailed description provided hereinafter. The detailed description of exemplary embodiments is intended for illustration purposes only and is, therefore, not intended to necessarily limit the scope of the disclosure.

### DETAILED DESCRIPTION

Exemplary embodiments of the present disclosure relate to a system having a resonant cavity at least partially filled with a dielectric material. The system also includes a laser source configured to emit a laser beam through a hole in the resonant cavity. An optical sensor captures at least a portion of laser beam that as passed through resonant cavity and generates a voltage based on the captured laser beam.

The exemplary embodiments described herein can be achieved by solving equation (4) for

$$\frac{df}{{dr}_{s}} ,$$

which results in

$$\frac{df}{{dr}_{s}} = \sqrt{\frac{- 32 π {T}^{00} {r}_{s}^{2}}{{ρ}^{2} {v}_{s}^{2}}} \qquad ( 5 )$$

Equation (5) suggests that the derivative of the shaping function with respect to the radius must be complex to have a positive energy density requirement. If the shaping function is allowed to have the following form,

$${f}_{c} ( {r}_{s} ) = {f}_{R} ( {r}_{s} ) + {if}_{I} ( {r}_{s} ) = {γ}_{R} f ( {r}_{s} ) + i {γ}_{I} f ( {r}_{s} ) = ( {γ}_{R} + i {γ}_{I} ) f ( {r}_{s} ) = γ f ( {r}_{s} ) . \qquad ( 6 )$$

$$then$$

$$\frac{{df}_{c} ( {r}_{s} )}{{dr}_{s}} = γ \frac{df ( {r}_{s} )}{{dr}_{s}} \qquad ( 7 )$$

$$and$$

$$\begin{matrix}{( \frac{{df}_{c}}{{dr}_{s}} )}^{2} = {{γ}^{2} ( \frac{df}{{dr}_{s}} )}^{2} \\ = {( {γ}_{R} + i {γ}_{I} )}^{2} {( \frac{df}{{dr}_{s}} )}^{2} \\ = ( {γ}_{R} + i {γ}_{I} ) ( {γ}_{R} + i {γ}_{I} ) {( \frac{df}{{dr}_{s}} )}^{2} \\ = ( {γ}_{R}^{2} + i {γ}_{R} {γ}_{I} - {γ}_{I}^{2} ) {( \frac{df}{{dr}_{s}} )}^{2}\end{matrix} \qquad ( 8 )$$

So then,

$$Re [ {( \frac{{df}_{c}}{{dr}_{s}} )}^{2} ] = ( {γ}_{R}^{2} - {γ}_{I}^{2} ) {( \frac{df}{{dr}_{s}} )}^{2} \qquad ( 9 )$$

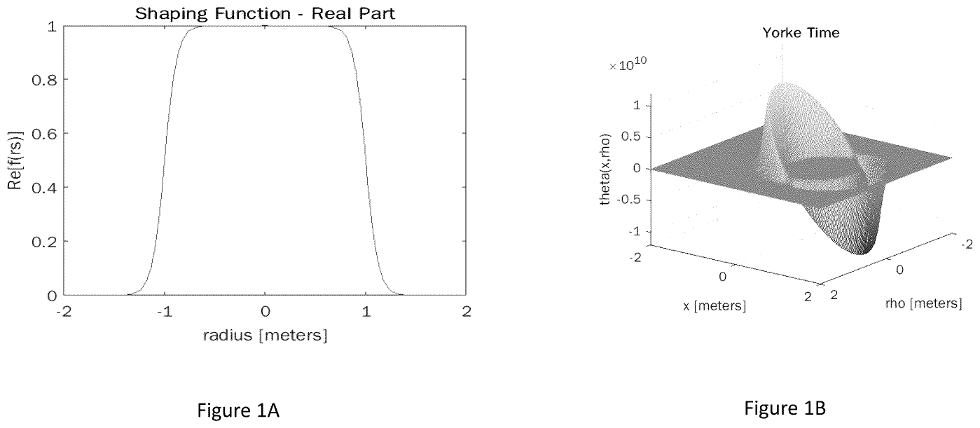

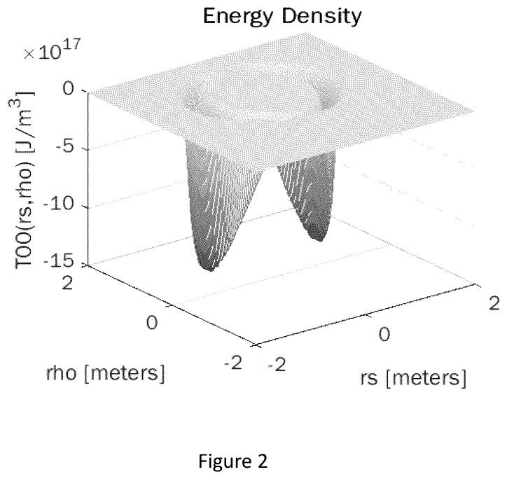

Therefore if |γ_{I}|>|γ_{R}| then the square of the derivative of the shaping function with respect to the radius is negative, which allows the required energy density distribution to be positive, and more of a manageable magnitude. If the values R=0.2 and I=0.6 are selected then an energy density distribution that provides the desired Yorke time structure shown in FIG. 1A is realized. Thus, if the shaping function is a complex relationship having an imaginary part greater than the real part, then the energy density required to distort space time can be positive. This property makes the generation and sustaining of a warp bubble sufficient for vehicle propulsion technologically achievable.

Materials having the property of a complex dielectric constant are preferred for use in accordance with exemplary embodiments described herein. An example of one such material is a simple coolant, ethylene glycol. At room temperature and 2.5 GHz the dielectric constant has a real part of 12.21 and an imaginary part of 14.52 (See Table 1). This material can fill a cavity and have a field introduced at the proper frequency and at a power level necessary to form a warp bubble.

TABLE 1
The dielectric constant and loss factor of ethanediol
at temperatures 10° C. and 20° C.

| | |
|---|---|
| 10° C. | 20° C. |

| F (GHz) | ε′ | ε″ | ε′ | ε″ |
|---|---|---|---|---|
| 0.01 | 44.30 | 0.55 | 41.89 | 0.33 |
| 0.02 | 44.28 | 1.10 | 41.88 | 0.52 |
| 0.03 | 44.23 | 1.66 | 41.89 | 0.70 |
| 0.04 | 44.18 | 2.20 | 41.83 | 1.04 |
| 0.05 | 44.10 | 2.75 | 41.80 | 1.39 |
| 0.06 | 44.01 | 3.29 | 41.76 | 1.74 |
| 0.07 | 43.90 | 3.82 | 41.72 | 2.06 |
| 0.08 | 43.78 | 4.36 | 41.67 | 2.42 |
| 0.09 | 43.64 | 4.88 | 41.61 | 2.77 |
| 0.1 | 43.49 | 5.40 | 41.54 | 3.11 |
| 0.2 | 41.24 | 10.09 | 40.53 | 3.45 |
| 0.4 | 34.63 | 16.06 | 37.07 | 6.68 |
| 0.6 | 28.16 | 18.14 | 32.74 | 11.92 |
| 0.8 | 23.13 | 18.13 | 28.51 | 15.21 |
| 1 | 19.47 | 17.29 | 24.83 | 16.81 |
| 1.2 | 16.81 | 16.20 | 21.80 | 17.30 |
| 1.4 | 14.85 | 15.10 | 19.36 | 17.14 |
| 1.6 | 13.38 | 14.07 | 17.40 | 16.63 |
| 1.8 | 12.24 | 13.14 | 15.82 | 15.97 |
| 2 | 11.34 | 12.30 | 14.53 | 15.24 |
| 2.5 | 9.77 | 10.60 | 12.21 | 14.52 |
| 3 | 8.77 | 9.31 | 10.70 | 12.86 |
| 3.5 | 8.09 | 8.31 | 9.66 | 11.47 |
| 4 | 7.60 | 7.51 | 8.91 | 10.32 |
| 4.5 | 7.22 | 6.86 | 8.35 | 9.38 |
| 5 | 6.93 | 6.31 | 7.92 | 8.59 |

The dielectric constant ε′ and the loss factor ε″ for temperatures 10° C. and 20° C. is presented in the Table 1. The above table showed that the dielectric constant ε′ is higher at low frequency (i.e. 44.30 at 0.01 GHz and 10° C.) and the loss factor ε″ is small at the same frequency and temperature (i.e. 0.55). The dielectric constant decreases as both frequency and temperature increases within the frequency range of 0.01 GHz to 0.2 GHz. However, at higher frequency range of 0.4 GHz to 5.0 GHz the dielectric constant increase as temperature increases

In addition to a material such as ethylene glycol, in other exemplary embodiments alternate materials such as metamaterials can be used.

In the work, Relativity: The special and general theory. New York: Holt, Einstein postulated that the gravitational pull between two bodies was due to the bending of space time that occurs due to the mass of the objects. The Alcubierre metric was formulated from Einstein's gravitational field equation formalism. It is known that a relationship between gravitational field equations and Maxwell's equations, which describe electromagnetic interactions. Further, electromagnetism can be formulated mathematically in Minkowski space. This suggests that electromagnetic fields have the potential to affect space time. The converse is clearly true as it is known that strong gravitational fields bend light, which can be characterized as an electromagnetic wave. A general solution to the wave equation, which comes from Maxwell's equations sets forth the expressions for the electric field E, as

$$E ( r , t ) = {E}_{0} {e}^{ikr} {e}^{- i ω t} ; \qquad ( 10 )$$

and the energy density due to the electric field is

$$u = ε {E}^{2} , \qquad ( 11 )$$

where ε is the permittivity of the medium. Our strategy is to construct a “warp core” from a resonant cavity filled with a dielectric material with complex permittivity. That is,

$$ε = {ε}^{′} + i {ε}^{″} = ( {ε}_{R}^{′} + i {ε}_{R}^{″} ) {ε}_{0} . \qquad ( 12 )$$

Inside of the cavity, the shaping function is the electric flux density D=εE. Under a transverse magnetic mode, particularly TM010, the field strength is maximum at the center of the cavity. A liquid material that has the complex permittivity of εR=12.21+14.52i at a frequency of around 2.4 GHz and a temperature of 20° C. As previously stated, if the imaginary part of the shaping function is greater than the real part, then the energy density distribution required to distort spacetime (Yorke time) in the manner shown is positive.

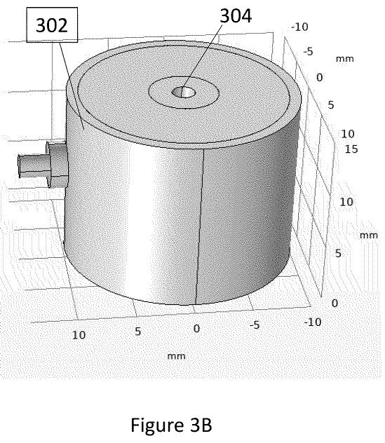

FIG. 3 shows a diagram of a cylindrical cavity in accordance with an exemplary embodiment of the present disclosure. The diameter of the cylinder 300 is calculated as a half wavelength in the material to be used. The phase velocity is calculated as v=c/√εR′, so then

$$λ = \frac{v}{f} = \frac{c}{f \sqrt{{ε}_{R}^{′}}} = 35.8 mm .$$

According to exemplary embodiments, to establish a TM₀₁₀ mode the radius of the cavity 302 can be 8.9 mm, and d/r<2.03, or d<18.09 mm. The objection is to create a region of warped spacetime at the center of the cavity 302. The cavity 302 is made such that there is a hole 304 down the center which will allow a laser beam 306 to pass through it through it unimpeded. If there is a perturbation of spacetime anywhere within this region, the laser beam will be slightly deflected.

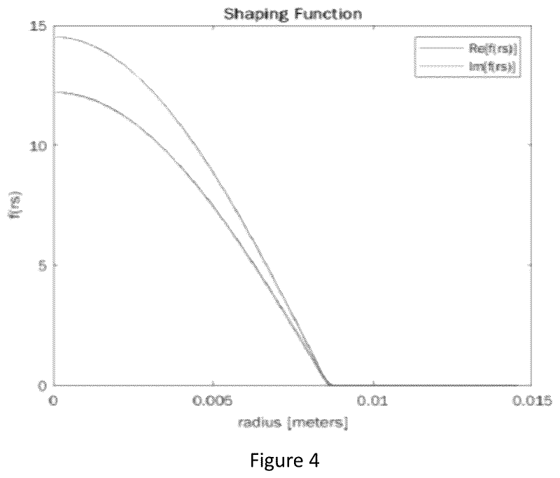

FIG. 4 illustrates a shaping function formed inside of the cylindrical cavity 302 based upon the electric flux density in TM010 mode in accordance with an exemplary embodiment of the present disclosure. Given the conditions set above, the shaping function, based upon the electric flux density has a cos(r) dependence with the real and imaginary parts of the function determined by the permittivity of the dielectric.

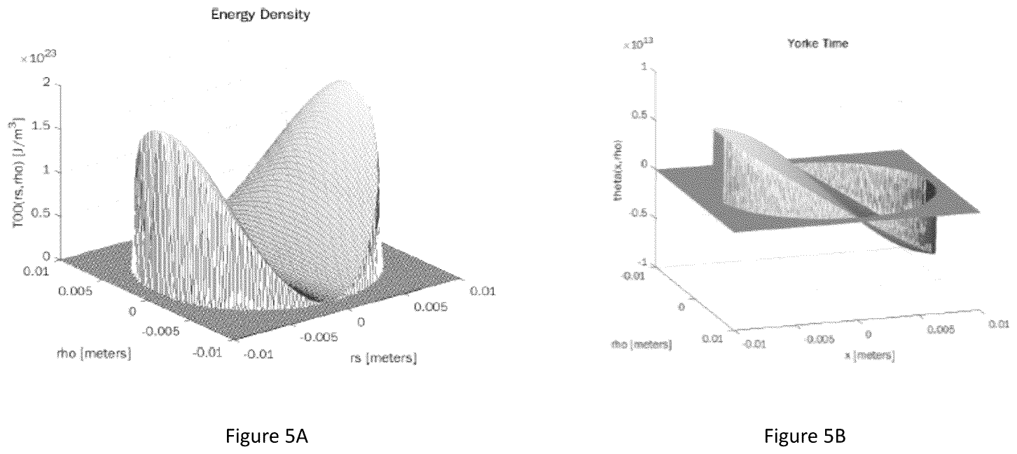

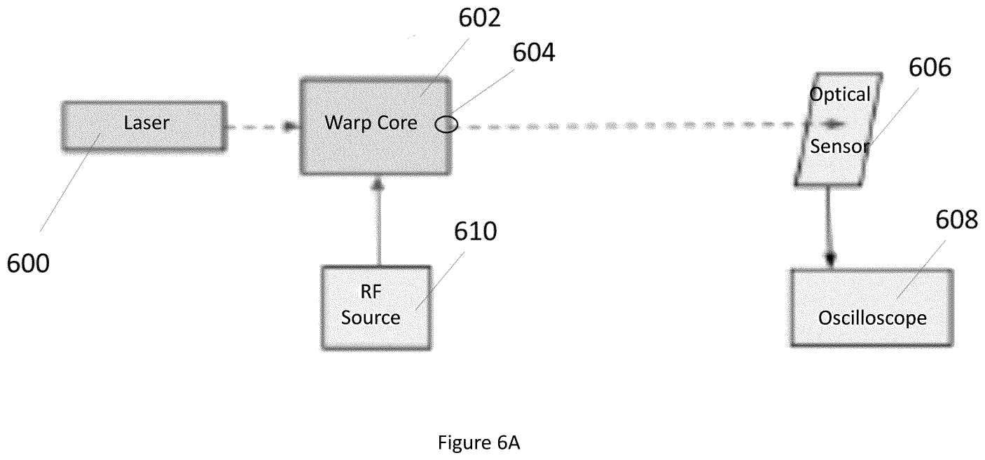

FIG. 5A illustrates an energy density distribution of the cylindrical resonant cavity filled with a lossy dielectric in accordance with an exemplary embodiment of the present disclosure. FIG. 5B illustrates a Yorke time structure based upon the cylindrical resonant cavity filled with a lossy dielectric in accordance with an exemplary embodiment of the present disclosure. Under the conditions shown in FIG. 4, the energy density representation is shown in FIG. 5A. It is positive and highest on the outer edges of the radius. The Yorke time response of FIG. 5B shows that in the region ahead of the “ship” spacetime is compressed and it is expanded in the region behind. There is only a negligible region where no spacetime compression or expansion occurs.

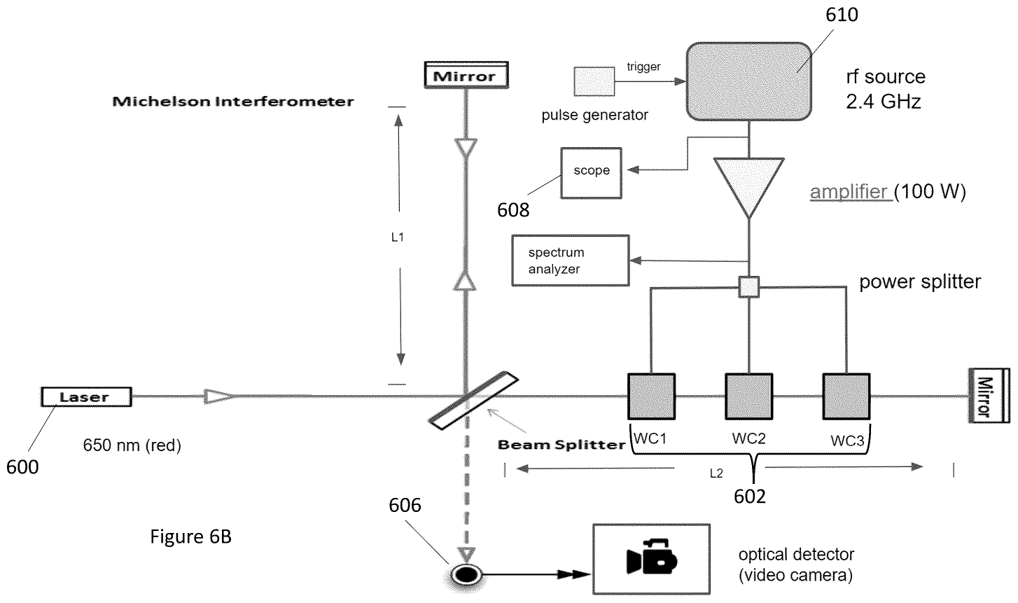

FIGS. 6A and 6B illustrate an exemplary systems for testing spacetime variations in accordance with an exemplary embodiment of the present disclosure. A 650 nm laser beam 600 is passed through the rf cavity 602 through the pass-through hole 604. It is captured by an optical sensor 606 whose voltage is measured by an oscilloscope 608. The rf cavity 602 is fed by a continuous 2.4 GHz source 610 at approximately 100 mW of power. Any fluctuations in voltage output to the scope will indicate that the laser beam 600 has been affected by alteration in spacetime near it. According to an exemplary embodiment of the present disclosure, the system can have the following properties and/or characteristics:
Cylindrical cavity diameter: 17.8 mm
Pass through hole diameter 1.5 mm
rf source power: 100 mW
rf source frequency: 2.4 GHz
Laser wavelength(s): 410, 532, 650 mm
Real Impedance in cavity: 78 Ohms

According to an exemplary embodiment, the resonant cavity is a cylinder having a diameter equal to a half wavelength of the dielectric material. The hole of the resonant cavity extends lengthwise along a center of the resonant cavity. An oscilloscope configured to measure the voltage generated by the optical sensor. The electromagnetic modes that are formed in a resonant cavity for different frequencies, dependent upon its geometry and the dielectric material it is filled with. These modes impact the position of the electric and magnetic field intensities and thus the energy density within the cavity. For the system of FIG. 6B, the rf power can be pulsed which will provide the following benefits: (1) management of temperature and power, (2) mitigation of noise effects, (3) allowing for accumulation of spacetime distortion in the affected region. Pulse shaping can be used to identify mechanisms in the formation of warp bubbles should they form.

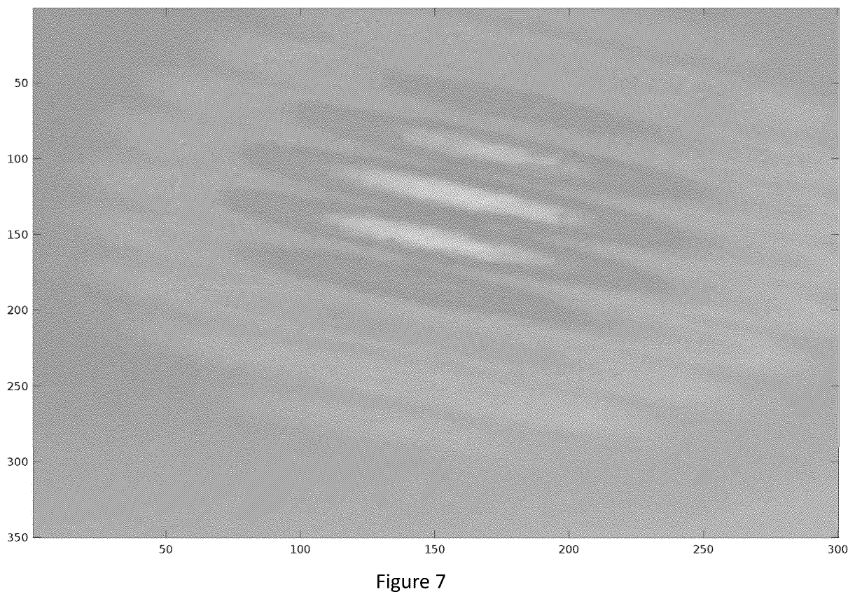

FIG. 7 illustrates an energy distribution plot generated by the systems of FIGS. 6A and 6B in accordance with an exemplary embodiment of the present disclosure.

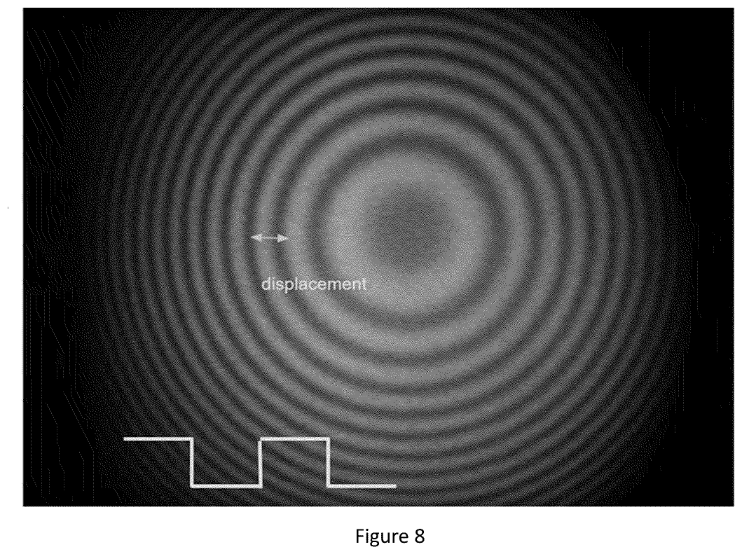

FIG. 8 illustrates interference fringes caused by distortion in the cylindrical resonant cavity in accordance with an exemplary embodiment of the present disclosure.

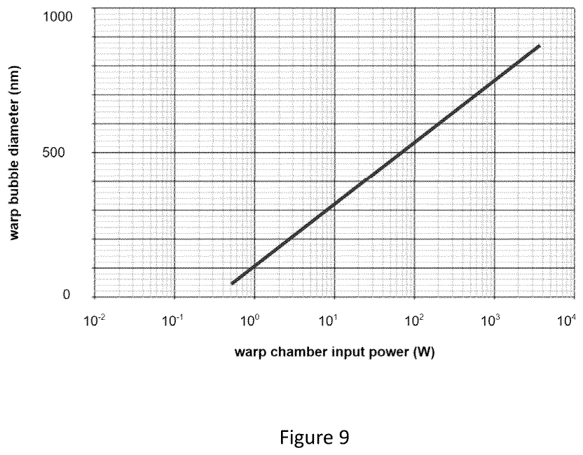

FIG. 9 illustrates a characterization curve showing the radius of a warp bubble formed in the resonant cavity in accordance with an exemplary embodiment of the present disclosure. As shown in FIG. 9, the diameter of the warp bubble increases with increased chamber input power.

According to an exemplary embodiment, the systems of FIGS. 6A and 6B can be varied in:
The radius of the cavity based upon a set of desired test frequencies and their resulting mode patterns.
The length of the cavities such that the desired dominant modes will be established as well as the potential for higher modes.
The material used for the cavity in order to optimize the temperature handling. For example, an increase input power leads to a change in the impact temperature has on the results.
The positioning of the through hole required to allow the laser interferometer beam to pass through uninterrupted.
The positioning of the rf signal input post in order to maximize the power transfer and reduce reflections back towards the source due to impedance mismatch.

The systems shown in FIGS. 6A and 6B also include a processor configured to determine whether energy of at least the portion of the laser beam captured at the output sensor fluctuates from energy of the laser beam emitted by the laser source. The processor can be configured to perform the operations disclosed herein through program code. Computer program code for performing the specialized functions described herein can be stored on a computer usable medium, which may refer to memories, such as the memory devices for the computing device 500, which can be memory semiconductors (e.g., DRAMs, etc.). These computer program products can be a tangible non-transitory means for providing software to the various hardware components of the respective devices as needed for performing the tasks associated with the exemplary embodiments described herein. The computer programs (e.g., computer control logic) or software can be stored in the memory device. The processor can be included in a computing device. According to an exemplary embodiment, the computer programs can also be received and/or remotely accessed via a receiving device of the computing device as needed. Such computer programs, when executed, can enable the computing device to implement the present methods and exemplary embodiments discussed herein, and may represent controllers of the computing device. Where the present disclosure is implemented using software, the software can be stored in a non-transitory computer readable medium and loaded into the computing device using a removable storage drive, an interface, a hard disk drive, or communications interface, etc., where applicable.

The computing device can include one or more processors that are configured to include one or more modules or engines configured to perform the functions of the exemplary embodiments described herein. Each of the modules or engines can be implemented using hardware and, in some instances, can also utilize software, such as program code and/or programs stored in memory. In such instances, program code may be compiled by the respective processors (e.g., by a compiling module or engine) prior to execution. For example, the program code can be source code written in a programming language that is translated into a lower level language, such as assembly language or machine code, for execution by the one or more processors and/or any additional hardware components. The process of compiling can include the use of lexical analysis, preprocessing, parsing, semantic analysis, syntax-directed translation, code generation, code optimization, and any other techniques that may be suitable for translation of program code into a lower level language suitable for controlling the computing device to perform the functions disclosed herein. It will be apparent to persons having skill in the relevant art that such processes result in the computing device being specially configured computing devices uniquely programmed to perform the functions discussed above.

It will be appreciated by those skilled in the art that the present invention can be embodied in other specific forms without departing from the spirit or essential characteristics thereof. The presently disclosed embodiments are therefore considered in all respects to be illustrative and not restrictive. The scope of the invention is indicated by the appended claims rather than the foregoing description and all changes that come within the meaning, range, and equivalence thereof are intended to be embraced therein.

What is claimed is:

1. A system comprising:
a resonant cavity at least partially filled with a dielectric material;
a laser source configured to emit a laser beam through a hole in the resonant cavity;
an optical sensor configured to capture at least a portion of laser beam that as passed through resonant cavity and generate a voltage based on the captured laser beam.

2. The system of claim 1, wherein the dielectric material has complex permittivity.

3. The system of claim 1, wherein the complex permittivity of the dielectric material is
$$ε = {ε}^{′} + i {ε}^{″} = ( {ε}_{R}^{′} + i {ε}_{R}^{″} ) {ε}_{0} .$$

4. The system of claim 1, wherein the dielectric material is a liquid.

5. The system of claim 1, wherein the resonant cavity is a cylinder having a diameter equal to a half wavelength of the dielectric material.

6. The system of claim 1, wherein the hole of the resonant cavity extends lengthwise along a center of the resonant cavity.

7. The system of claim 1, comprising:
an oscilloscope configured to measure the voltage generated by the optical sensor.

8. The system of claim 7, wherein a warp field is generated in the resonant cavity when at least the portion of the laser beam captured by the optical sensor is distorted.

9. The system of claim 8, comprising:
a processor configured to determine whether energy of at least the portion of the laser beam captured at the output sensor fluctuates from energy of the laser beam emitted by the laser source.

10. A method for warping space time, the method comprising:
filling a resonant cavity at least partially with a dielectric material;
emitting a laser beam through a hole in the resonant cavity; and
capturing, at least a portion of laser beam that as passed through resonant cavity and generate a voltage based on the captured laser beam.

11. The method of claim 10, comprising:
measuring, by an oscilloscope, the voltage generated by the optical sensor.

12. The method of claim 11, comprising:
distorting, by the resonant cavity, at least the portion of the laser beam captured by the optical sensor; and
generating, by the resonant cavity, a warp field based on the distortion of at least the portion of the laser beam.

13. The method of claim 12, comprising:
determining, by a processor, whether energy of at least the portion of the laser beam captured at the output sensor fluctuates from energy of the laser beam emitted by the laser source.
